(19) United States
(12) Patent Application Publication
(10) Pub. No.: US 2025/0164565 A1
(43) Pub. Date: May 22, 2025

(54) METHOD FOR MANAGING VEHICLE-MOUNTED POWER BATTERY BASED ON STOCHASTIC THEORY

(71) Applicant: SHANDONG UNIVERSITY, SHANDONG (CN)

(72) Inventors: Chenghui ZHANG, SHANDONG (CN); Fazheng WEN, SHANDONG (CN); Bin DUAN, SHANDONG (CN); Rui ZHU, SHANDONG (CN); Junming ZHANG, SHANDONG (CN)

(73) Assignee: SHANDONG UNIVERSITY, SHANDONG (CN)

(21) Appl. No.: 19/033,521

(22) Filed: Jan. 22, 2025

Related U.S. Application Data
(63) Continuation-in-part of application No. 17/614,547, filed on Nov. 28, 2021.

(30) Foreign Application Priority Data
May 28, 2019 (CN) 201910452182.9

(51) Int. Cl. G01R 31/367; B60L 58/12; B60L 58/16; G01R 31/3828

(52) U.S. Cl. CPC G01R 31/367; B60L 58/12; B60L 58/16; G01R 31/3828

(57) ABSTRACT

The present invention discloses a method for managing vehicle-mounted power battery based on stochastic theory, comprising: current source applies current excitation signal to power battery mounted on vehicle by control of BMS, and obtaining voltage measurement signal of the power battery; reconstructing voltage response signal that can effectively restore true voltage of the power battery by processing input and output signals of power battery; obtaining battery model parameters based on reconstructed voltage response signal and current excitation signal; estimating physical parameter values of internal state of power battery based on extended Kalman filter, unscented Kalman filter and like; charging the power battery timely, checking and maintaining the power battery, or replacing the power battery by comparing estimated physical parameter values of internal states with corresponding threshold values.

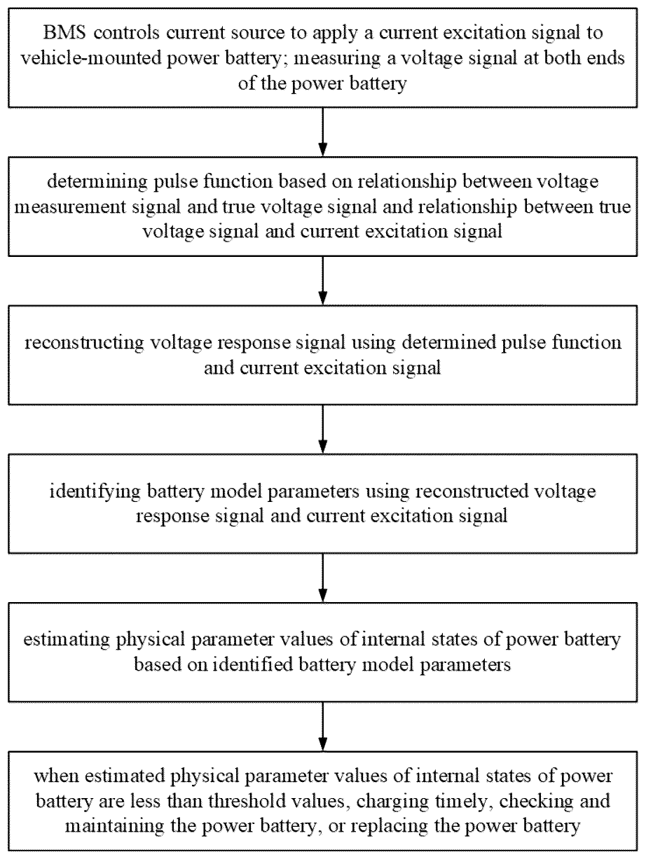

### CROSS-REFERENCES TO RELATED APPLICATIONS

The present invention is a continuation-in-part application of a prior U.S. application Ser. No. 17/614,547, filed on Nov. 28, 2021. The prior U.S. application Ser. No. 17/614,547 is a 371 of international application of PCT application serial no. PCT/CN2020/092937, filed on May 28, 2020, which claims priority to Chinese application No. 201910452182.9, filed on May 28, 2019. The entirety of each of the above-mentioned patent applications is hereby incorporated by reference herein and made a part of this specification.

### TECHNICAL FIELD

The present invention belongs to the technical field of identification of battery model parameters, and in particular to a method for managing a vehicle-mounted power battery based on stochastic theory.

### BACKGROUND

The description in this section merely provides background information related to the present invention and does not necessarily constitute the prior art.

As a main power source and a core component of electric vehicles, lithium-ion batteries have become a hot application and research focus due to unique advantages in energy density, power density, cycle life, service life, self-discharge rate and the like. In order to ensure safe, reliable and efficient operation of power batteries, a vehicle-mounted battery management system (BMS) needs to be used to accurately estimate and predict various states of the batteries, such as state of charge (SOC), state of health (SOH), state of power (SOP) and state of energy (SOE). However, these internal states cannot be directly obtained by external measurement means and need to be indirectly estimated, and a battery model is often used as a basis for estimating the states of the batteries. Wherein, equivalent circuit models are widely used due to advantages such as simple structure, low calculation amount, and easy engineering realization. It needs to apply an excitation signal to the power battery to obtain an response signal thereof, so that model parameters can be obtained through identification based on input and output signals of the power battery and battery parameter identification algorithms such as least squares, particle swarm optimization, genetic algorithm, etc., thus various states of the battery are further estimated or predicated by using extended Kalman filter, unscented Kalman filter, etc., Therefore, the precision of the input and output signals of the power battery is very important to the accuracy of identification of the model parameters and estimation of the battery states.

However, the inventor found that due to the influence of electromagnetic interference generated by high-power devices in electric vehicles and sensors, the input and output signals of the power battery actually measured usually have errors, which easily leads to inaccurate identification of battery parameters and inability to accurately estimate the battery state. In view of this situation, one conventional method performs filtering processing on the input and output signals of the battery, for example, filtering noise signals by using a low-pass Butterworth filter, etc., but this method has problems that it is difficult to set the filter order and cutoff frequency, and the filtering effect is not ideal.

### SUMMARY

In order to solve the above problems, the present invention provides a method for managing a vehicle-mounted power battery based on stochastic theory, wherein a current source applies a current excitation signal to a power battery mounted on a vehicle under a control of a vehicle-mounted BMS on the vehicle, a voltage response signal of the power battery is obtained; the BMS processes the input and output signals of the power battery, and reconstructs the voltage response signal of battery, then identifies the battery model parameters based on the reconstructed voltage response signal and current excitation signal, and further estimates physical parameter values of various current internal states of the vehicle-mounted power battery by using extended Kalman filter, unscented Kalman filter and other methods; finally, by comparing the physical parameter values of the states with their corresponding threshold values, performing related operations such as timely charging, checking and maintenance, and even replacement of the power battery.

In some implementation modes, the following technical solution is adopted.

The present invention provides a method for managing a vehicle-mounted power battery based on stochastic theory, comprising:
applying, by a current source, a current excitation signal to a power battery mounted on a vehicle under a control of a BMS, and obtaining a voltage measurement signal by measuring a voltage at both ends of the power battery by the BMS;
determining, by the BMS, a pulse function based on a relationship between the voltage
measurement signal and a true voltage signal and a relationship between the true voltage signal and the current excitation signal;
reconstructing, by the BMS, a voltage response signal based on the pulse function and the current excitation signal;
identifying, by the BMS, battery model parameters by using the reconstructed voltage
response signal and the current excitation signal; and
estimating, by the BMS, physical parameter values of internal state of the power battery based on the identified battery model parameters;
wherein, when the estimated physical parameter values of the internal states of the power battery are less than threshold values, charging the power battery timely, checking and maintaining the power battery, or replacing the power battery.

Further, the internal states of the power battery comprise, but are not limited to, one or more of SOC, SOH, SOP, or SOE.

Compared with the prior art, the present invention has the following beneficial effects:

i) Good authenticity of reconstructed output signal, high parameter identification accuracy and accurate internal state estimation.

Wherein, in the process of reconstructing the voltage response signal of the power battery, convolution principle and correlation function calculation are adopted, and the pulse function between the current excitation signal and the true voltage signal is obtained by mathematical theory analysis, then the voltage response signal of the power battery is obtained by convolving the pulse function with the current excitation signal. The voltage response signal is very close to the real voltage signal, so that the identified battery model parameters have higher accuracy and the estimation of internal states is more accurate.

ii) Good realizability and high practical value.

Wherein, the reconstructed voltage response signal is calculated based on mathematical theory analysis, without involving the setting of Butterworth filter order, cut-off frequency and other parameters, avoiding complex parameter optimization process and the algorithm is simple and easy to implement, with high practical value.

### BRIEF DESCRIPTION OF THE DRAWINGS

The accompanying drawings constituting a part of the present invention are used to provide a further understanding of the present invention. The exemplary examples of the present invention and descriptions thereof are used to explain the present invention, and do not constitute an improper limitation of the present invention.

FIGURE is a flow chart of steps of a method for managing a vehicle-mounted power battery based on stochastic theory according to one example of the present invention.

### DESCRIPTION OF THE EMBODIMENTS

It should be noted that the following detailed descriptions are all exemplary and are intended to provide further descriptions of this application. Unless otherwise specified, all technical and scientific terms used in the present invention have the same meaning as commonly understood by a person of ordinary skill in the art to which this application belongs.

It should be noted that terms used herein are only for describing specific implementations and are not intended to limit exemplary implementations according to this application. As used herein, the singular form is intended to include the plural form, unless the context clearly indicates otherwise. In addition, it should be further understood that terms “comprise” and/or “comprising” used in this specification indicate that there are features, steps, operations, devices, assemblies, and/or combinations thereof.

### Example 1

In one or more embodiments, providing a high-precision battery model parameter identification method based on output response reconstruction, comprising the following steps:

(1) determining a pulse function based on a relationship between a voltage measurement signal and a true voltage signal and a relationship between the true voltage signal and a current excitation signal.

A specific implementation is as follows:

1) Obtaining a functional relationship between the voltage response signal and the current excitation signal of the power battery based on a convolution principle.

If the power battery stays in a stable state, there is the relationship between the current excitation I(k) and an output voltage U(k) shown in Formula (1):

$$U ( k ) = {\sum }_{m = 0}^{∞} g ( k - m ) I ( m ) = {\sum }_{m = 0}^{∞} g ( m ) I ( k - m ) , \qquad ( 1 )$$

where, g(m) denotes the value of the pulse function at time m.

Influenced by electromagnetic interference generated by high-power devices of electric vehicles, sensors and other factors, actually measured voltage signals are usually influenced by noises, so the present invention adopts pulse function ĝ and the current excitation signal I to reconstruct the voltage signal Û, and identifies battery model parameters based on the voltage signal Û and the current signal I; wherein, the battery model comprises but is not limited to equivalent circuit model, electrochemical model and the like. In terms of accuracy, the reconstructed voltage signal Û is greatly improved compared with the actual measured voltage signal, so the accuracy of battery model parameter identification is guaranteed, and the accuracy of estimation values of physical parameters of internal states of the battery will be higher.

2) Obtaining the pulse function ĝ based on correlation functions.

Assuming that a relationship between the voltage measurement signal Uₘ(k), the true voltage signal Uₜ(k) and a noise signal Vₙ(k) is shown in Formula (2):

$${U}_{m} ( k ) = {U}_{t} ( k ) + {V}_{n} ( k ) \qquad ( 2 )$$

In addition, there was a relationship between Uₜ(k) and the current excitation I(k) shown in the Formula (1), then a correlation function (CF) R_{UI}(λ) between Uₘ(k) and I(k) may be written to:

$${R}_{UI} ( λ ) = E \{ I ( k - λ ) {U}_{m} ( k ) \} . \qquad ( 3 )$$

Further, the Formula (3) can be written to:

$${R}_{UI} ( λ ) = E \{ I ( k - λ ) ( {\sum }_{m = 0}^{∞} \hat{g} ( m ) I ( k - m ) + {V}_{n} ( k ) ) \} . \qquad ( 4 )$$

And, furthermore, the Formula (4) can be written to:

$${R}_{UI} ( λ ) = {\sum }_{m = 0}^{∞} \hat{g} ( m ) {R}_{II} ( λ - m ) + E \{ I ( k - λ ) {V}_{n} ( k ) \} . \qquad ( 5 )$$

Since the current excitation signal I(k) is not related to the voltage noise signal Vₙ(k), then:

$$E \{ I ( k - λ ) {V}_{n} ( k ) \} = 0. \qquad ( 6 )$$

Then, Formula (7) can be obtained by substituting the Formula (6) into the Formula (5), as follows:

$${R}_{UI} ( λ ) = {\sum }_{m = 0}^{∞} \hat{g} ( m ) {R}_{II} ( λ - m ) . \qquad ( 7 )$$

Rewriting the Formula (7) into a matrix form, then obtaining:

$$( \begin{matrix}{R}_{UI} ( 0 ) \\ {R}_{UI} ( 1 ) \\ \cdot \\ \cdot \\ \cdot \\ \cdot \\ {R}_{UI} ( N - 1 )\end{matrix} ) = ( \begin{matrix}{R}_{II} ( 0 ) & {R}_{II} ( - 1 ) & \text{...... .} & {R}_{II} ( - N + 1 ) \\ {R}_{II} ( 1 ) & {R}_{II} ( 0 ) & \text{...... .} & {R}_{II} ( - N + 2 ) \\ \cdot & & \cdot & \\ \cdot & & \cdot & \\ \cdot & & \cdot & \\ \cdot & & \cdot & \\ {R}_{II} ( N - 1 ) & {R}_{II} ( N - 2 ) & \text{...... .} & {R}_{II} ( 0 )\end{matrix} ) \times ( \begin{matrix}\hat{g} ( 0 ) \\ \hat{g} ( 1 ) \\ \cdot \\ \cdot \\ \cdot \\ \cdot \\ \hat{g} ( N - 1 )\end{matrix} ) . \qquad ( 8 )$$

A pseudo-random sequence signal is used as the battery excitation signal, and an autocorrelation function (ACF) R_{II}(λ) of the pseudo-random sequence signal is as follows:

$${R}_{II} ( λ ) = \{ \begin{matrix}{a}^{2} , & λ = 0 \\ - \frac{{a}^{2}}{N} , & 1 \leq λ \leq N - 1\end{matrix} . \qquad ( 9 )$$

Then, let

$$ϕ = ( \begin{matrix}{R}_{II} ( 0 ) & {R}_{II} ( - 1 ) & \text{...... .} & {R}_{II} ( - N + 1 ) \\ {R}_{II} ( 1 ) & {R}_{II} ( 0 ) & \text{...... .} & {R}_{II} ( - N + 2 ) \\ \cdot & & & \cdot \\ \cdot & & & \cdot \\ \cdot & & & \cdot \\ \cdot & & & \cdot \\ {R}_{II} ( N - 1 ) & {R}_{II} ( N - 2 ) & \text{...... .} & {R}_{II} ( 0 )\end{matrix} ) . \qquad ( 10 )$$

And then, the pulse function ĝ may be written to:

$$\hat{g} = {ϕ}^{- 1} {R}_{UI} ( λ ) , \qquad ( 11 )$$

where, a is an amplitude of an excitation signal, N is a quantity of sampling points; R_{II}(λ) is an even function, therefore, when λ is a negative number, a value of R_{II}(λ) is consistent with a value when λ is positive.

The function R_{UI}(λ) further may be written to:

$${R}_{UI} ( λ ) = \frac{1}{N} {\sum }_{m = 0}^{N - 1} {U}_{m} ( m ) I ( m - λ ) . \qquad ( 12 )$$

Finally, the pulse function ĝ is obtained by substituting the formulas (9), (10) and (12) into the Formula (11).

(2) The voltage signal is reconstructed based on the pulse function and the current excitation signal.

Convolution operation is performed on the obtained pulse function ĝ and the current excitation I to obtain a reconstructed voltage Û, and the precision of the voltage is much higher than that of a voltage obtained after filtering with a general low-pass filter. This process can be implemented by a person of ordinary skill in the art according to the prior art and is not described in detail.

(3) Equivalent circuit model parameters of the battery are obtained based on the reconstructed voltage signal and the current excitation signal.

Equivalent circuit model parameters with high precision of the battery can be obtained by using a recursive least square algorithm based on the reconstructed voltage Û and the current excitation I. This process can be implemented by a person of ordinary skill in the art according to the prior art and is not described in detail.

### Example 2

In one or more embodiments, providing a high-precision battery model parameter identification system based on output response reconstruction, comprising:
a module for determining a pulse function based on a relationship between a voltage measurement signal and a true voltage signal and a relationship between the true voltage signal and a current excitation signal;
a module for reconstructing a voltage signal based on the pulse function and the current excitation signal; and
a module for obtaining equivalent circuit model parameters of a battery based on the reconstructed voltage signal and the current excitation signal.

### Example 3

In one or more embodiments, providing a terminal device, comprising a server, the server includes a memory, a processor and a computer program which is stored on the memory and can run on the processor. The high-precision battery model parameter identification method based on output response reconstruction in Example 1 is implemented when the processor executes the program. For brevity, details are not described herein again.

It should be understood that in this embodiment, the processor may be a central processing unit (CPU); or the processor may be another general purpose processor, a digital signal processor (DSP), an application-specific integrated circuit (ASIC), a field programmable gate array (FPGA) or another programmable logical device, a discrete gate or a transistor logical device, a discrete hardware component, or the like. The general-purpose processor may be a microprocessor, or the processor may be any conventional processor and the like.

The memory may comprise a read-only memory or a random-access memory, and provides an instruction and data to the processor. A part of the memory may further include a non-volatile random-access memory. For example, the memory may further store information about a device type.

During implementation, the steps of the foregoing method may be completed through an integrated logic circuit of hardware or an instruction in the form of software in the processor.

The steps of the methods disclosed with reference to Example 1 may be directly embodied as being implemented by a hardware processor or by a combination of hardware and software modules in a processor. The software module may be located in a mature storage medium in the field such as a random access memory, a flash memory, a read-only memory, a programmable read-only memory, an electrically erasable programmable memory, or a register. The storage medium is located in the memory. The processor reads information in the memory and uses hardware thereof to implement the steps of the foregoing methods. To avoid repetition, details are not described herein again.

A person of ordinary skill in the art may notice that the exemplary units and algorithm steps described with reference to this embodiment can be implemented in electronic hardware, or a combination of computer software and electronic hardware. Whether to execute the functions in hardware or software mode depends on particular applications and design constraint conditions of the technical solutions. A person skilled in the art may use different methods to implement the described functions for each particular application, but it is not to be considered that the implementation goes beyond the scope of this application.

The specific implementations of the present invention are described above, but are not intended to limit the protection scope of the present invention. A person skilled in the art should understand that various modifications or deformations may be made without creative efforts based on the technical solutions of the present invention, and such modifications or deformations shall fall within the protection scope of the present invention.

### Example 4

Based on the detailed descriptions of above examples, in one or more embodiments, the present example provides a method for managing a vehicle-mounted power battery based on stochastic theory, as shown in FIGURE, comprising the following steps:
Step 1: applying, by a current source, a current excitation signal to a power battery mounted on a vehicle under a control of a BMS, and obtaining a voltage measurement signal by measuring a voltage at both ends of the power battery by the BMS, simultaneously;
Step 2: determining, by the BMS, a pulse function based on a relationship between the voltage measurement signal and a true voltage signal and a relationship between the true voltage signal and the current excitation signal;
Step 3: reconstructing, by the BMS, a voltage response signal based on the pulse function and the current excitation signal;
Step 4: identifying, by the BMS, battery model parameters by using the reconstructed voltage response signal and the current excitation signal; wherein, the battery model parameters comprise but are not limited to the model parameters in a electrochemical model or an equivalent circuit model;
Step 5: estimating, by the BMS, physical parameter values of internal state of the power battery based on the identified battery model parameters;
Step 6: when the estimated physical parameter values of the internal states of the power battery are less than threshold values, charging the power battery timely, checking and maintaining the power battery, or replacing the power battery.

Wherein, the contents described in Step 2 to Step 4 can be executed through the specific steps of the high-precision battery model parameter identification method based on output response reconstruction described in Example 1, so the specific process will not be described in detail.

In Step 5, based on the obtained battery model, physical parameter values of the internal states of the power battery can be estimated using methods such as extended Kalman filter, unscented Kalman filter, particle filter, etc. This process is achievable by ordinary technical personnel in this field based on existing technology, so the specific process will not be described in detail.

In one or more embodiments, the internal states of the power battery comprise but are not limited to one or more of SOC, SOH, SOP, or SOE.

In one or more embodiments, the threshold values are predetermined threshold values for normal use of the power battery and can be set by those skilled in the art based on the actual usage scenario, usage requirements, standard specifications, etc. of the power battery, and the present invention will not make specific limitations here.

### Example 5

Based on the detailed descriptions of above examples, in one or more embodiments, the present example provides a system for managing a vehicle-mounted power battery based on stochastic theory, comprising:
a current source, controlled by a BMS mounted on a vehicle, configured to apply a current excitation signal to a power battery mounted on the vehicle;
the BMS, comprises:
a module for measuring a voltage measurement signal at both ends of the power battery while applying the current excitation signal;
a module for determining a pulse function based on a relationship between the voltage measurement signal and a true voltage signal and a relationship between the true voltage signal and the current excitation signal;
a module for reconstructing a voltage response signal based on the pulse function and the current excitation signal;
a module for identifying battery model parameters by using the reconstructed voltage response signal and the current excitation signal;
a module for estimating physical parameter values of internal state of the power battery based on the identified battery model parameters.

Wherein, when the estimated physical parameter values of the internal states of the power battery are less than threshold values, charging the power battery timely, checking and maintaining the power battery, or replacing the power battery.

The above description is only a preferred implementation of the present invention, but the scope of protection of the present invention is not limited thereto, and any equivalent replacement or change made by those skilled in the art according to the technical solution and the inventive concept of the present invention within the technical scope disclosed by the present invention shall be covered by the scope of protection of the present invention.

What is claimed is:

1. A method for managing a vehicle-mounted power battery based on stochastic theory, comprising:
applying, by a current source, a current excitation signal to a power battery mounted on a vehicle under a control of a BMS (battery management system) mounted on the vehicle, and obtaining a voltage measurement signal by measuring a voltage at both ends of the power battery by the BMS simultaneously;
determining, by the BMS, a pulse function based on a relationship between the voltage measurement signal and a true voltage signal and a relationship between the true voltage signal and the current excitation signal;
reconstructing, by the BMS, a voltage response signal based on the pulse function and the current excitation signal;
identifying, by the BMS, battery model parameters by using the reconstructed voltage response signal and the current excitation signal; and
estimating, by the BMS, physical parameter values of internal state of the power battery based on the identified battery model parameters;
wherein, when the estimated physical parameter values of the internal states of the power battery are less than threshold values, charging the power battery timely, checking and maintaining the power battery, or replacing the power battery.

2. The method for managing the vehicle-mounted power battery based on stochastic theory according to claim 1, wherein the relationship between the voltage measurement signal and the true voltage signal is specifically:
$${U}_{m} ( k ) = {U}_{t} ( k ) + {V}_{n} ( k ) ,$$
where, Uₘ(k) is the voltage measurement signal, Uₜ(k) is the true voltage signal, and Vₙ(k) is a noise signal.

3. The method for managing the vehicle-mounted power battery based on stochastic theory according to claim 1, wherein the relationship between the true voltage signal and the current excitation signal is specifically:
$${U}_{t} ( k ) = {\sum }_{m = 0}^{∞} g ( m ) I ( k - m ) ,$$
where, Uₜ (k) is the true voltage signal, I(k−m) is the current excitation signal, and g(m) is a value of the pulse function at time m.

4. The method for managing the vehicle-mounted power battery based on stochastic theory according to claim 1, wherein the pulse function is specifically:
$$\hat{g} = {ϕ}^{- 1} {R}_{UI} ( λ ) ,$$
$$where ϕ = ( \begin{matrix}{R}_{II} ( 0 ) & {R}_{II} ( - 1 ) & \text{...... .} & {R}_{II} ( - N + 1 ) \\ {R}_{II} ( 1 ) & {R}_{II} ( 0 ) & \text{...... .} & {R}_{II} ( - N + 2 ) \\ \cdot & & & \cdot \\ \cdot & & & \cdot \\ \cdot & & & \cdot \\ \cdot & & & \cdot \\ {R}_{II} ( N - 1 ) & {R}_{II} ( N - 2 ) & \text{...... .} & {R}_{II} ( 0 )\end{matrix} ) , \\ {R}_{II} ( λ ) = \{ \begin{matrix}{a}^{2} , & λ = 0 \\ - \frac{{a}^{2}}{N} , & 1 \leq λ \leq N - 1\end{matrix} ,$$
a is an amplitude of an excitation signal, N is a quantity of sampling points, and R_{II}(λ) is an even function; therefore, when λ is a negative number, a value of R_{II}(λ) is consistent with a value of the R_{II}(λ) when the λ is positive; and,
$${R}_{UI} ( λ ) = \frac{1}{N} {\sum }_{m = 0}^{N - 1} {U}_{m} ( m ) I ( m - λ ) ,$$
where Uₘ(m) is the voltage measurement signal and I(m−λ) is the current excitation signal.

5. The method for managing the vehicle-mounted power battery based on stochastic theory according to claim 1, wherein obtaining the reconstructed voltage response signal by performing a convolution operation on the obtained pulse function and the current excitation signal.

6. The method for managing the vehicle-mounted power battery based on stochastic theory according to claim 1, wherein the internal states of the power battery comprise, but are not limited to, one or more of state of charge (SOC), state of health (SOH), state of power (SOP) and state of energy (SOE).
